(19) United States
(12) Patent Application Publication
(10) Pub. No.: US 2013/0222962 A1
(43) Pub. Date: Aug. 29, 2013

(54) CIRCUIT BOARD METER FOR CIRCUIT BREAKERS

(71) Applicants: Hilmir Ingi Jonsson, Grindavik (IS); Jon Thor Olafsson, Gardabaer (IS); Snorri Hreggvidsson, Mosfellsbaer (IS)

(72) Inventors: Hilmir Ingi Jonsson, Grindavik (IS); Jon Thor Olafsson, Gardabaer (IS); Snorri Hreggvidsson, Mosfellsbaer (IS)

(73) Assignee: REMAKE ELECTRIC EHF, Hafnarfjordur (IS)

(21) Appl. No.: 13/641,037

(22) PCT Filed: Apr. 14, 2011
(86) PCT No.: PCT/IS2011/050006

§ 371 Date: May 14, 2013

(30) Foreign Application Priority Data
Apr. 14, 2010 (IS) 8891
Sep. 10, 2010 (IS) 8927

(51) Int. Cl. G01R 19/15

(52) U.S. Cl. CPC G01R 19/15
USPC 361/115; 324/96

(57) ABSTRACT

A current measuring device for circuit breakers with an improved electronic circuit arrangement by way of arrangement and method for displaying electrical line current by a circuit breaker wherein measurements are made by at least one current transformer. Indications of the magnitude of electrical current are displayed by at least one LED and by the intensity of illumination by each LED. The current measuring device is placed onto a circuit breaker wherein at least one LED of the improved circuit is made accessible by sight at the front face of the current measuring device attached to the circuit breaker. A current transformer is located inside the current measuring device attached to the circuit breaker for measuring the current flowing through the conductor applied to the circuit breaker. The current transformer supplies the improved electronic circuit with a reduced electrical current in proportion to the electrical current flowing through the conductor displaying the magnitude of the current by strength of illumination by at least one LED.

### FIELD OF THE INVENTION

The present invention relates generally to electrical current level indication in conjunction with circuit breakers. More particularly but not exclusively, it relates to an electronic metering circuit accessory for indicating electrical current level in conjunction with circuit breakers.

### BACKGROUND OF THE INVENTION

Circuit breakers are known in the art to be used to hold electrical line current and trip the current by overload or short circuit incidents. Circuit breakers generally have a switch to activate and/or deactivate electrical current connection through the circuit breakers, wherein the switch furthermore indicates an ON or OFF state of the circuit breaker to identify if electrical current is active or not. Because of these limited information means by circuit breakers integration of electrical measurements and indications have been provided by circuit breakers to provide information regarding electrical parameters by circuit breakers.

Circuit breakers are known to be capable of displaying ON, OFF and TRIP statuses by auxiliary switching means incorporated by the circuit breaker to be operable to a plurality of different switching conditions of the circuit breaker. Also, circuit breakers have been arranged to comprise current level indications regarding parameters of current value by the circuit breakers using sensing resistors and amplifiers to energize indicating LEDs on the front face of circuit breakers. Furthermore, circuit breakers have been arranged to indicate parameters of current value by a LED wherein the light signals can be formatted to be detectable by an operable receiving device.

### SUMMARY OF THE INVENTION

Although all preceding circuit breakers provide integrated status indications to be accessible on the front face of circuit breakers there remains a need for an improved electronic measuring circuit for indicating distinctive load state by magnitude of illumination by LEDs. Also due to dimensional constrains of conventional circuit breakers and dependable operation of electronic measuring circuits in various load states by circuit breakers there remains a need for an improved analogue circuit to operate in conjunction with circuit breakers. Furthermore, there also remains a need for providing an undemanding metering accessory to conventional circuit breakers in which can also transmit measurements to central processing units or computers. The invention is provided to resolve these and other problems.

It is an object of the present invention is to provide a solution for measuring and displaying the electrical load in a system using a circuit breaker and a metering device, which is either an individual component attached to a circuit breaker or is an integrated part of the circuit breaker. The improved electronic measuring circuit device of the present invention, together with a circuit breaker unit displays the proportional magnitude of the AC-line current in use by the circuit breaker. The improved circuit does not comprise any processing means by a CPU or digital means for operation, but is an analogue circuit which is able to display proportional electrical line current by varying magnitude of illumination by at least one LED.

Another object of the present invention is to improve reliability of AC line current measurements by circuit breakers by excessive current loads.

A further objective of the present invention is to provide to the consumer accessible information regarding real-time electrical line current through a circuit breaker without compromising the function of the circuit breaker.

Furthermore, in addition to the LED display or as an alternative to the LEDs, sound signal warnings are provided to notify overload situations by a buzzer.

Yet another object of the present invention is to provide an enhanced approach for professionals to diagnose and monitor/analyse the electrical load state by each circuit breaker of the invention.

In a first aspect of the present invention a current measuring device or accessory for circuit breakers is provided. The current measuring device comprises a current transformer and an analogue electronic circuit. The analogue electronic circuit further comprises transistors, resistors and at least one LED. The current measuring device is characterised in that the current measuring device is powered by the current transformer, which is placed around a wire or a conductor and produces a reduced current proportional to the current flowing through the wire or conductor. The current measuring device is further characterised in that the at least one LED illuminates in proportion to the magnitude of the load current passing through the current transformer.

In a second aspect of the present invention a circuit breaker with a current measuring unit is provided. The circuit breaker comprises a housing, a switch, line terminals and load terminals, wherein the current measuring unit comprises a current transformer and an analogue electronic circuit. The analogue electronic circuit further comprises transistors, resistors, and at least one LED positioned on a housing of the circuit breaker. The current measuring unit is powered by the current transformer, placed around a wire or a conductor and produces a reduced current proportional to the current flowing through the wire or conductor and the at least one LED illuminates in proportion to the magnitude of the load current passing through the current transformer.

In a third aspect of the present invention a busbar with a current measuring unit is provided. The busbar comprises a housing and copper or aluminium conductors and the current measuring unit comprises a at least one current transformer and an analogue electronic circuit. The analogue electronic circuit further comprises transistors, resistors, and at least one LED positioned on a housing of the circuit breaker, wherein the current measuring unit is powered by the current transformer, placed around a wire or a conductor and produces a reduced current proportional to the current flowing through the wire or conductor. Furthermore, the at least one LED illuminates in proportion to the magnitude of the load current passing through the current transformer.

### DESCRIPTION OF THE INVENTION

The advantage of the current metering device of the present invention is that a) a traditional (magnetic coil) current transformer is used to detect the current, which allows the metering device to detect the load and by producing reduced current accurately proportional to the current flowing through the circuit breaker, b) the CT is connected to an analogue circuit with one or more LEDs. The combination of a CT and the analogue circuit provides a measuring device for circuit breakers, which can handle a much greater load than current metering devices by resistor sensing effects such as meter shunts and Hall effects. A further advantage is that it can display gradual increase in load through intensity of illumination by the one or more LEDs or by turning on additional LEDs as the load increases. In addition to these advantages the electronic measuring circuit device of the present invention also has output means by “connection terminal” for conveying the current in the circuit breaker to a computer by an analogue signal. This is possible as the magnetic CT has produced a reduced current reflecting the actual current in the circuit breaker which can be carried by the connection terminal.

Another advantage of the present invention is that the current metering assembly provided here can either be built into a traditional circuit breaker or as a device which is attached to the circuit breaker to provide current load indications on the front face of the traditional circuit breaker. By adding the current metering device to a traditional circuit breaker for providing information on electrical line current by the said circuit breaker an advantage is found to monitor operation of electrical appliances to avoid long-term over-load operation. With the current metering device, traditional circuit breakers can be improved by current metering abilities.

The present invention regards an improved electronic circuit arrangement managing a current transformer to produce the operating power to the indicating LEDs of the circuit. The electronic circuit can be arranged in at least one fraction or component wherein the circuit is arranged to be a part of a copper-flex circuit assembly by at least one part of the circuit. All items of the arrangement are current operated including the current transformer and as the current from the transformer increases to energize the LEDs then more LEDs will be lighted as the current transformer produces a reduced current proportional to the current in the circuit breaker. Therefore as the current increases in the circuit breaker the current transformer will transmit the proportional current from a conductor, connected to the circuit breaker, to the electronic circuit in which a transistor of each LED of the circuit will direct the excess current towards the next LED subsequently and can ultimately direct the current towards a buzzer. By these means the LEDs will illuminate in series and in magnitude as the line current increases and indicate the actual load in use by the circuit breaker. Levels of the current magnitude can be indicated by number of LEDs and the magnitude of the illumination of each LED and thus the current metering device always displays the absolute proportional electrical line current flowing through the circuit breaker. Additionally when the line current has reached or exceeded the breaking rate of a circuit breaker a buzzer can be activated as an addition or as an alternative to a LED for overload warning signals.

The following embodiments relate to all aspects of the invention, i.e. a current measuring device, a circuit breaker including the current measuring unit is and a busbar with a current measuring unit.

In an embodiment of the present invention the analogue electric circuit comprises an array of LEDs, which may have the same colour or wherein the array of LEDs have different colours.
In an embodiment of the present invention each LEDs in the array of LEDs is gradually lid from low to high intensity before the next LED is lid due to increased current passing through the current transformer. Furthermore, each LEDs in the array of LEDs is gradually lid from a first LED to the next LED due to increased current passing through the current transformer.

In an embodiment of the present invention the circuit comprises means for producing a sound signal, such as a buzzer.

In an embodiment of the present invention the current measuring device is an accessory and is externally attached to a circuit breakers housing. Furthermore, the current transformer is detachable from the accessory.

In an embodiment of the present invention the analogue electric circuit is in at least one part a copper-flex ribbon. Furthermore, the circuit comprises at least one NPN or PNP transistor to direct electrical current from a current transformer to a LED.
In an embodiment of the present invention the circuit breaker comprises the analogue electronic circuit inside the circuit breakers housing or as a part of the circuit breakers housing. Furthermore, the current transformer can be integrated to the circuit breakers housing or be detachable from the circuit breakers housing.

In an embodiment of the present invention the current measuring device further comprises output means for transmitting the reduced current signal from the current transformer.

In the present context the current measuring unit, although integrated to the circuit breakers housing or a bus bar, is not connected to the circuit breakers mechanism nor the conductor connected to the circuit breaker and thus does not affect the operation of the circuit breaker.

The electronic circuit of the present invention including the current transformer can be a part of the circuit breakers housing wholly and/or partially, furthermore it can additionally or as an alternative be an attachment to the circuit breakers housing. The circuit could therefore be arranged to be integrated to at least one part of the circuit breakers housing whereas different parts of the circuit could wholly or partially be placed in various parts of the circuit breakers housing or in at least one part of an attachment to the circuit breakers housing. The circuit could be arranged to be a part of a component in which is attached to or by a circuit breaker wherein the component could also comprise or be connected to at least one current transformer. The current transformer could be arranged to be fitted inside the component or as an alternative could be arranged to be attached to the component wherein the component could comprise click-on means for attachment to the circuit breakers housing and/or to the current transformer. In an embodiment of the invention wherein the circuit is in at least two parts and conductors such as copper wires or a copper-flex ribbon comprising copper wires could be used to connect different circuit parts together wherein the ribbon could be separate to or as a part of a component to be attached to a circuit breaker. The LEDs of the circuit could be arranged to be a part of the copper-flex ribbon.

In another embodiment the circuit parts and the ribbon is integrated to the circuit breaker or to the circuit breakers housing separately.

The current transformer could be arranged to comprise a resistor to adapt to various load ratings of circuit breakers and could be arranged to be externally exchangeable to the circuit breakers housing or the components housing. The load adapting resistor could alternatively or as an addition be a part of the electronic circuit of the invention. The component could also be arranged to comprise the warning buzzer of the circuit as an alternative to the buzzer being housed in the circuit breaker. The buzzer could also be arranged to be a separate device attached to the component via input/output terminal.

The electronic circuit in accordance to the present invention is constructed to display the proportional value of the current in conjunction with the rating limit of protection of each circuit breaker thus the operator or user can identify and confirm how much load is used in conjunction with the maximum tripping limit of the circuit breaker and can also be able to receive by sight and/or by sound warnings of an overload situation of each circuit breaker.

In the present context the current measuring device can be used with or is compatible and constructible with at least a one pole embodiment of a AC current miniature circuit breaker and furthermore can be arranged for AC current moulded case circuit breakers and residual current circuit breakers.

The current measuring device of present invention can furthermore be arranged to comprise an input/output connection element wherein measurements or the reduced current signals from the current transformer can be transmitted to external computers or the alike via busbar, conductors or wires connected to the said connection element. Also, as an alternative to such an embodiment the current metering device can be arranged to be without the electronic circuit wherein measurements or a reduced current are sent directly from the current transformer to external computers or the alike. The current transformer could in such an embodiment be in an external component in which is fitted onto a circuit breaker or be partially or wholly integrated to a circuit breaker and could be detachable from the circuit breaker or could be a part of a busbar.

In yet another embodiment the current measuring device can be arranged to be fastened to a circuit breaker wherein a conductor, in which is to be connected to the said circuit breaker, is instead connected to the housing of the current measuring device wherefrom the conductor obtains connection with the circuit breaker.

Furthermore, the invention can be a part of a busbar to be connected and fastened to circuit breakers. In such an embodiment conductors are connected to at least one circuit breaker linked to the busbar in which at least one current transformer is partially or wholly a part of said busbar used to measure current to each circuit breaker attached to the said busbar. As an addition to the busbar an input/output connection element for linking the current transformer to computers or the alike could partially or wholly be a part of the busbar. The busbar could comprise the electronic circuit and could be arranged to have a front face or a cover element in which holds at least one LED linked to the electronic circuit to be accessible to a consumer for displaying measurements from the current transformer. The said front face or cover element comprising the electronic circuit could be arranged to be detachable from the busbar.

### Description of drawings

FIG. 1 is a table diagram for illustrating the function details of the invention according to conjunction characteristics amid line current and light magnitude by each LED.

FIG. 2 is a detailed circuit schematic of the inventions arrangement and items.

FIG. 3 is a perspective view of an embodiment of a traditional miniature circuit breaker where the current measuring device is attached to the front side of the miniature circuit breaker.

FIG. 4 is a perspective view of an embodiment of a miniature circuit breaker incorporating the current measuring device, where a current transformer is selectable and detachable.

FIG. 5 is a perspective view of an embodiment of a miniature circuit breaker incorporating the whole current measuring device.

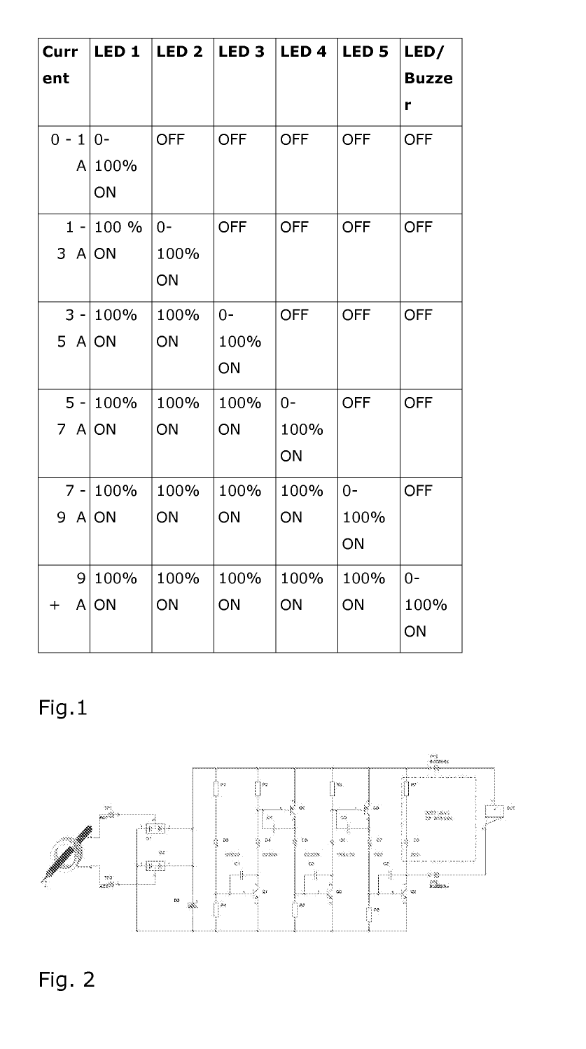

In FIG. 1 a table of an embodiment of the electronic circuit displays the conjunction of indications by the LEDs according to a 10 Amp protection circuit breaker. Variations to this table will be dependant to the size of the current transformer in accordance to the maximum rating of a circuit breaker. The indications are characterized as the first LED will start to illuminate after line current is activated and be fully illuminated by 1 Amp. Before the line current reaches 1 Amp other LEDs will be inactive, however subsequently after exceeding 1 Amp the second LED will start to illuminate and be fully illuminated by 3 Amps as will the first LED although other LEDs will remain inactive. The third LED will start to illuminate as the line current exceeds 3 Amps and be fully illuminated by 5 Amps as will the previous two LEDs while other LEDs of the circuit will remain inactive until the line current exceeds 5 Amps. The fourth LED will start to illuminate by 5 Amps and be fully illuminated along with previous LEDs by 7 Amps while other LEDs or buzzer will remain inactive. When line current through the current metering device exceeds 7 Amps then the fifth LED will be active and start to illuminate and be fully illuminated by 9 Amps along with previous LEDs while the last LED or buzzer will be active when the line current exceeds 9 Amps by illuminating or sounding a warning signal to indicate overload situation.

In FIG. 2 a circuit diagram for showing details of a preferred arrangement of the inventions electronic circuit wherein a current transformer, 5 light emitting diodes (LEDs) and a buzzer are managed, however the circuit could be arranged to have fewer or additional LEDs to indicate current levels. The circuit is powered by a current transformer which is disposed on a wire or connection means and supplies power through terminals TP1/AC1 and TP2/AC2 which connects to the initial stage of the circuits arrangement which is a full wave rectifier comprised of diodes D1 and D2 preferably types of diodes in which can to lower voltage from the transformer will be used. Current will start to flow in LED D3 and as the line current increases then NPN transistor Q1 will start to feed current to the next LED D4 and when current in LED D4 increases the PNP transistor Q4 will open and direct excess current to LED D5. When current in LED D5 increases the NPN transistor Q2 will open and direct excess current to LED D6. When current in LED D6 increases the PNP transistor Q5 will direct excess current to LED D7 and when current in LED D7 increases the NPN transistor Q3 will direct excess current to a Buzzer (SU1) through terminals TP3 and TP4 which could alternatively or in addition be LED D8. Excessive current flows through diode D9.

The foregoing described function of the invention has the advantage of displaying concurrent electrical line current corresponding to the breaking limit set by each circuit breaker. The arrangement has the advantage of not requiring processors to decode measurements and not requiring amplifiers to power LEDs by sensed current. Although the foregoing description is directed to a certain embodiment of the invention it is not to be exclusive to the description wherein one skilled in the art will realize additional alternatives from the disclosure of the said embodiment. The circuit of FIG. 2 could be arranged to comprise two diodes and two capacitors instead of a full wave rectifier by the diodes of D1 and D2 to form a power increase to the circuit from the current transformer. This arrangement would increase power flow to the circuit while reducing strain from the current transformer.

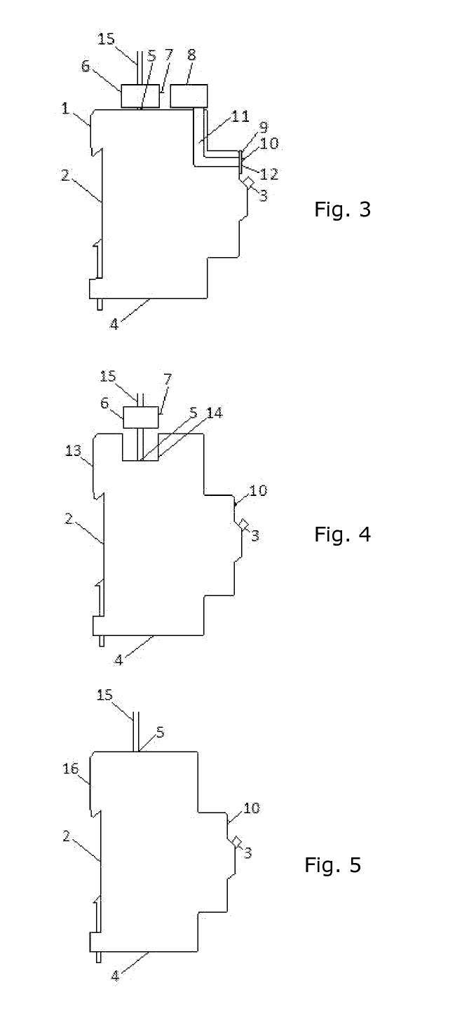

In FIG. 3 an embodiment of a traditional miniature circuit breaker device (1) is exhibited to include a DIN rail mounting attachment (2) wherein the circuit breaker (1) is attached and fastened to a DIN rail preferably inside electrical panels. The circuit breaker (1) also has a switch (3) for activating or deactivating electrical current through the device (1).

The circuit breaker (1) has an input terminal (4) for connecting to the electrical current supply wherein the current is controlled by the circuit breakers (1) switch (3) which when activated allows the current supply from the input terminal (4) to flow through the breaker (1) and through the output terminal (5) supplying, by conductor (15), the line current to be protected. In this embodiment of the current measuring device having a current transformer (6) is placed on top of the circuit breakers housing (1) wherein a conductor (15) is inserted through the current transformer (6) and fastened to the output terminal (5) of the breakers housing (1). The current transformer (6) produces a reduced current accurately proportional to the active line current flowing by the conductor (15) and transmits the reduced current to an electronic circuit (9) in which indicates the active line current from the conductor (15) by at least one LED (10) in accurate current proportion from the current transformer (6). The LED (10) is arranged to indicate a certain rate of line current and furthermore by the magnitude of light emitted the magnitude of line current is indicated by illumination of the LED (10). Additionally a selective number of LEDs (10) by the circuit (9) could be arranged to indicate various magnitudes or rates of line current from the conductor. Also various types and sizes of current transformers (6) can be managed to be attached to a component which is attachable to the circuit breakers housing (1) and correspond to the maximum rated current for a range of circuit breakers (1) with various maximum rated current protection. The current transformer (6) has output terminals (7) to be connected to the electronic circuit (9) partially integrated to the component (8) wherein connections to another part of the circuit (9) are arranged to be through the component (8) in which is attached to the circuit breakers housing (1). The component (8) possesses a part of the circuit (9) which directs the current from the current transformer (6) to the LED (10) of the circuit (9) at the front face of the circuit breakers housing (1). The circuit (9) on the front face of the breaker (1) is adjoined to a cover (12) in which is attached to the front face of the breaker (1) wherein at least one LED (10) is made accessible through the cover (12). A connection from the component (8) to the circuit (9) on the front face is made able by a copper-flex ribbon (11) in which is preferably glued to the side of the breakers housing (1). The attachable component (8) also possesses a warning buzzer (not shown) in which is a part of the circuit (9) and alerts of the maximum line current rating of the breaker (1). A resistor (not shown) is assembled to the current transformer (6) as to transmit accurate proportions of current corresponding to the maximum rating of each circuit breaker (1), thus the resistor can be of various sizes and could also be assembled to the circuit (9) inside the component (8). The electronic circuit (9) along with the copper-flex ribbon (11) and the component (8) could be arranged to be a part of or as a united module, also as an addition or as an alternative the current transformer (6) could be a part of such a module, in which is attached to the circuit breakers housing (1). The current transformer (6) could transmit measurements via conductors or wires (not shown) directly or through connection from the component (8) to external computers. In such an alternative embodiment the invention can be arranged to be without the electronic circuit (9) and the indicating LEDs (10) and only provide transmitted measurements.

Although the foregoing description is directed to a certain embodiment of the invention it is not to be exclusive to the description wherein one skilled in the art will realize additional alternatives from the disclosure of the said embodiment.

In FIG. 4 an embodiment of a miniature circuit breaker device (13) of the invention is exhibited to include a DIN rail mounting attachment (2) wherein the circuit breaker (13) is attached and fastened to a DIN rail preferably inside electrical panels. The circuit breaker (13) also has a switch (3) for activating or deactivating electrical current through the device (13) wherein the circuit breaker (13) has an input terminal (4) for connecting to the electrical current supply. The current flow is controlled by the circuit breakers (13) switch (3) which when activated allows the current supply from the input terminal (4) to flow through the breaker (13) and through the output terminal (5) supplying, by conductor (15), the line current to be protected. By this embodiment the circuit breaker (13) has an opening (14) in its housing (13) for inserting a current transformer (6) onto, wherein various types and sizes of current transformers (6) can be managed to be inserted and attached to the opening (14), and correspond to the maximum rated current for a range of circuit breakers (13) with various maximum rated current protection. The current transformers (6) output terminals (7) are inserted to the breakers housing (13) and connected to the electronic circuit (9) integrated by the breakers housing (13). The circuit breaker (13) also possesses an internal warning buzzer (not shown) in which is a part of the circuit (9) and alerts of the maximum line current rating of the breaker (13). A resistor (not shown) is assembled to the current transformer (6) as to transmit accurate proportions of current corresponding to the maximum rating of each circuit breaker (13), thus the resistor can be of various sizes and could also be assembled to the circuit (9) inside the breakers housing (13). The circuit (9) is furthermore placed inside the front segment of the breakers housing (13) wherein at least one LED (10) is made accessible on the front face of the breakers housing (13). The reduced current flowing from the current transformer (6) is transmitted to the circuit (9) wherein the circuit (9) indicates the accurate proportion of current flowing through the circuit breaker (13) by at least one LED (10). The magnitude of the current flowing through the breaker (13) is indicated by number of LEDs (10) and by the magnitude of illumination of emitted light from each LED (10). A part of the circuit (9) is integrated in the upper part of the circuit breakers housing (13) and connectable to the selectable and detachable current transformer (6) wherein connections from the upper part circuit (9) to the integrated part of the circuit placed in the front face of the circuit breaker (13) is made able through an integrated cooper-flex ribbon (11). The electronic circuit (9) along with the copper-flex ribbon (11) could be arranged to be a part of the miniature circuit breakers housing (13) itself as an alternative to being integrated inside the circuit breakers assembled housing (13). The circuit breaker device (13) could be arranged to transmit measurements from the current transformer (6) via conductors or wires (not shown) connected to the circuit breakers housing (13) to external computers. In such an alternative embodiment the circuit breaker (13) could be arranged to be without the electronic circuit (9) and the indicating LEDs (10) and only provide transmitted measurements.

Although the foregoing description is directed to a certain embodiment of the invention it is not to be exclusive to the description wherein one skilled in the art will realize additional alternatives from the disclosure of the said embodiment.

In FIG. 5 an embodiment of a miniature circuit breaker device (16) of the invention is exhibited to include a DIN rail mounting attachment (2) wherein the circuit breaker (16) is attached and fastened to a DIN rail preferably inside electrical panels. The circuit breaker (16) also has a switch (3) for activating or deactivating electrical current through the device (16) wherein the circuit breaker (16) has an input terminal (4) for connecting to the electrical current supply. The current flow is controlled by the circuit breakers (16) switch (3) which when activated allows the current supply from the input terminal (4) to flow through the breaker (16) and through the output terminal (5) supplying, by conductor (15), the line current to be protected. By this embodiment the circuit breaker (16) has an integrated current transformer (6) wherein various types and sizes of current transformers (6) can be managed to be integrated corresponding to the maximum rated current for a range of circuit breakers (16) with various maximum rated current protection. The current transformers (6) output terminals (7) are connected to the electronic circuit (9) integrated by the breakers housing (16). The circuit breaker (16) also possesses an internal warning buzzer (not shown) in which is a part of the circuit (9) and alerts of the maximum line current rating of the circuit breaker (16). A resistor (not shown) is assembled to the integrated current transformer (6) as to transmit accurate proportions of current corresponding to the maximum rating of each circuit breaker (16), thus the resistor can be of various sizes and could also be assembled to the circuit (9) inside the circuit breakers housing (16). The circuit (9) is furthermore placed inside the front segment of the breakers housing (16) wherein at least one LED (10) is made accessible on the front face of the breakers housing (16). The reduced current flowing from the current transformer (6) is transmitted to the circuit (9) wherein the circuit (9) indicates the accurate proportion of current flowing through the circuit breaker (16) by at least one LED (10). The magnitude of the current flowing through the breaker (16) is indicated by number of LEDs (10) and by the magnitude of illumination of emitted light from each LED (10). A part of the circuit (9) is integrated in the upper part of the circuit breakers housing (16) and connectable to the selectable and detachable current transformer (6) wherein connections from the upper part circuit (9) to the integrated part of the circuit placed in the front face of the circuit breaker (16) is made able through an integrated cooper-flex ribbon (11). The electronic circuit (9) along with the copper-flex ribbon (11) and the current transformer (6) could be arranged to be a part of the miniature circuit breakers housing (16) as an alternative to being integrated to the mechanism inside the circuit breakers assembled housing (16). As an alternative embodiment of the circuit breaker device (16) the current transformer (6) can transmit measurements via conductors or wires (not shown) connected to the circuit breakers housing (16) to external computers. In such an embodiment the circuit breaker (16) could be arranged to be without the electronic circuit (9) and the indicating LEDs (10) and only provide transmitted measurements.

Although the foregoing description is directed to a certain embodiment of the invention it is not to be exclusive to the description wherein one skilled in the art will realize additional alternatives from the disclosure of the said embodiment.

All the foregoing descriptions of the invention may as an alternative or an addition to miniature circuit breakers be in the form of a moulded case circuit breaker or a residual current circuit breaker and comprise at least one pole of whichever circuit breaker embodiment previously mentioned.

1-23. (canceled)

24. A current measuring device for circuit breakers , the current measuring device comprising:
current transformer,
analogue electronic circuit , further comprising:
transistors,
resistors, and
at least one indicating LED,
characterized in that the current measuring device is powered by the current transformer to produce the operating power to the indicating LEDs, said current transformer is placed around a wire or a conductor and produces a reduced current proportional to the current flowing through the wire or conductor; and wherein the current measuring device is configured to indicate a distinctive current state by magnitude of illumination by at least one LED which illuminates in proportion to the magnitude of the current passing through the current transformer.

25. The current measuring device according to claim 24, wherein the analogue electric circuit comprises an array of LEDs .

26. The current measuring device according to claim 25, wherein the array of LEDs has different colours.

27. The current measuring device according to claim 25, wherein each LEDs in the array of LEDs is gradually lid from low to high intensity before the next LED is lid due to increased current passing through the current transformer.

28. The current measuring device according to claim 25, wherein each LEDs in the array of LEDs is gradually lid from a first LED to the next LED due to increased current passing through the current transformer.

29. The current measuring device according to claim 24, wherein the analogue circuit comprises a buzzer.

30. The current measuring device according to claim 24, wherein the current measuring device is an accessory and is externally attached to a circuit breaker's housing.

31. The current measuring device according to claim 24, wherein the current transformer is detachable from the current measuring device.

32. The current measuring device according to claim 24, wherein the analogue electric circuit is in at least one part a copper-flex ribbon.

33. The current measuring device according to claim 24, wherein the analogue electric circuit comprises at least one NPN or PNP transistor to direct electrical current from a current transformer to a LED .

34. The current measuring device according to claim 24, wherein the current measuring device further comprises output means for transmitting the reduced current signal from the current transformer .

35. A circuit breaker with a current measuring device according to any of the preceding claims, the circuit breaker comprising:
a housing,
a switch,
line terminals, and
load terminals.

36. The circuit breaker according to claim 35, wherein the circuit breaker comprises the analogue electronic circuit inside the circuit breaker's housing.

37. The circuit breaker according to claim 35, wherein the circuit breaker comprises the analogue electronic circuit as a part of the circuit breaker's housing.

38. The circuit breaker according to claim 35, wherein the circuit breaker comprises said current transformer being integrated to the circuit breaker's housing.

39. The circuit breaker according to claim 35, wherein the current transformer of the measuring unit is be detachable from the circuit breaker's housing.

40. The circuit breaker according to claim 35, wherein the circuit breaker comprises output means for transmitting the reduced current signal from the current transformer .

41. The circuit breaker according to claim 35, wherein the circuit breaker displays at least one LED on the circuit breaker's housing.
